(19) United States
(12) Patent Application Publication
(10) Pub. No.: US 2025/0318070 A1
(43) Pub. Date: Oct. 9, 2025

(54) FAN CAGE AND PERIPHERAL COMPONENT INTERFACE SYSTEM FOR DESKTOP WORKSTATIONS

(71) Applicant: Lenovo (Singapore) Pte. Ltd., Singapore (SG)

(72) Inventors: Matthew Sean Hilliard, Raleigh, NC (US); Rodrigo Samper, Wallace, NC (US)

(21) Appl. No.: 18/629,708

(22) Filed: Apr. 8, 2024

(51) Int. Cl. H05K 7/20; G06F 1/18; G06F 1/20; H05K 7/14

(52) U.S. Cl. CPC H05K 7/20172; G06F 1/183; G06F 1/20; H05K 7/1409; H05K 7/20145

(57) ABSTRACT

A peripheral component interconnect (PCI) for a desktop workstation includes a housing, levers attached to the housing, compartments for one or more fans, a retainer for a PCI card, and electrical couplings for coupling to a printed circuit board (PCB) on the workstation.

### TECHNICAL FIELD

Embodiments described herein generally relate to desktop workstations, and in an embodiment, but not by way of limitation, a fan cage and peripheral component interface system for desktop workstations.

### BACKGROUND

Processor-based desktop workstations normally include fans and/or fan cages to cool the processors of the workstation. These fans and/or fan cages are attached to the frame of the desktop workstation via screws and/or other fasteners, and therefore require one or more hand tools to remove the fans and/or fan cages. The fans and/or fans cages also are connected to the mother board via cables that provide power and control signals to the fans.

### BRIEF DESCRIPTION OF THE DRAWINGS

In the drawings, which are not necessarily drawn to scale, like numerals may describe similar components in different views. Like numerals having different letter suffixes may represent different instances of similar components. Some embodiments are illustrated by way of example, and not limitation, in the figures of the accompanying drawings.

FIG. 1 is a first view of an embodiment of a fan cage and peripheral component interface for a desktop workstation.

FIG. 2 is a second view of an embodiment of a fan cage and peripheral component interface for a desktop workstation.

FIG. 3 is a third view of an embodiment of a fan cage and peripheral component interface for a desktop workstation.

FIG. 4 is a fourth view of an embodiment of a fan cage and peripheral component interface for a desktop workstation.

### DETAILED DESCRIPTION

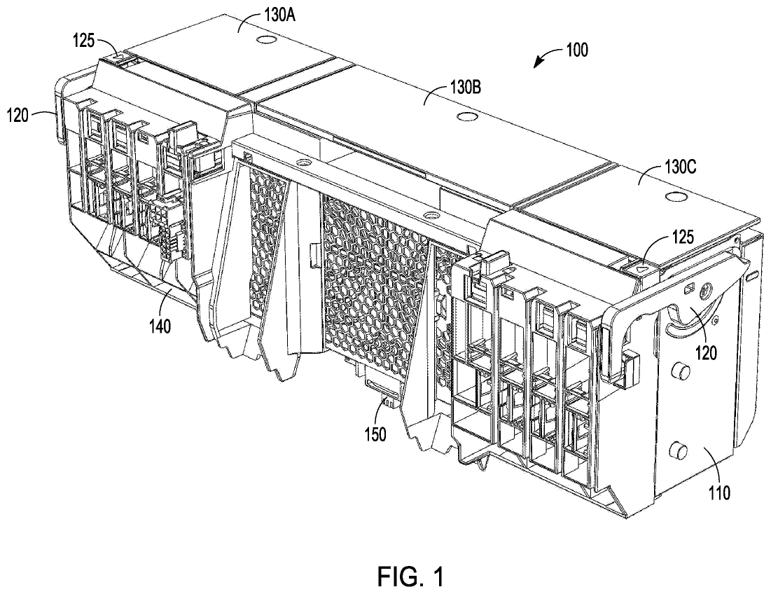

FIG. 1 is a perspective view of an embodiment of a fan cage and peripheral component interface (PCI) 100 for a desktop workstation. The embodiment has a housing 110. Attached to the housing 110 on both sides of the housing are levers 120. The levers 120 are released from an installed position with the assistance of release buttons 125. As will be explained herein, the levers act as cams when installing the embodiment into a workstation and also assist in removing the housing from the workstation. The embodiment of FIG. 1 further includes fan compartments 130A, 130B and 130C. Other embodiments can have fewer or more fan compartments. The embodiment still further includes a retainer 140 for holding a PCI card. On the underside of the housing 110, there are one or more electrical couplings 150. The one or more electrical couplings 150 serve to couple the embodiment to a printed circuit board of the desktop workstation, and the couplings provide power to the fans and receive control signals from the mother board of the desktop workstation.

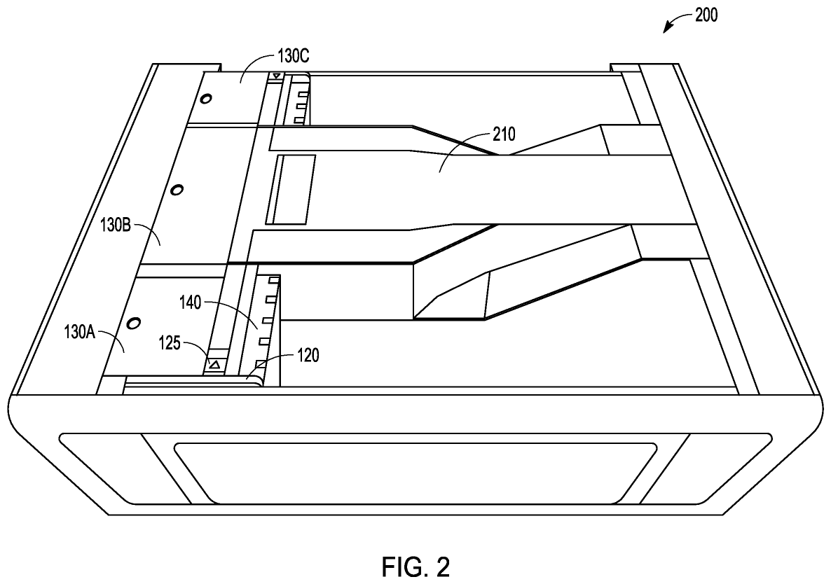

FIG. 2 illustrates the system 100 installed in a desktop workstation 200. Visible in FIG. 2 are the levers 120, release buttons 125, retainer 140 and the fan compartments 130A, 130B and 130C. Also visible in FIG. 2 is a baffle 210, which receives airflow from the fans in the fan compartments 130A, 130B and 130C and directs that airflow down into the innards of the workstation 200. It is noted that the fan compartments 130A, 130B and 130C can either be removed from the housing 110 as a single unit, or each individual compartment can be removed separately from the housing.

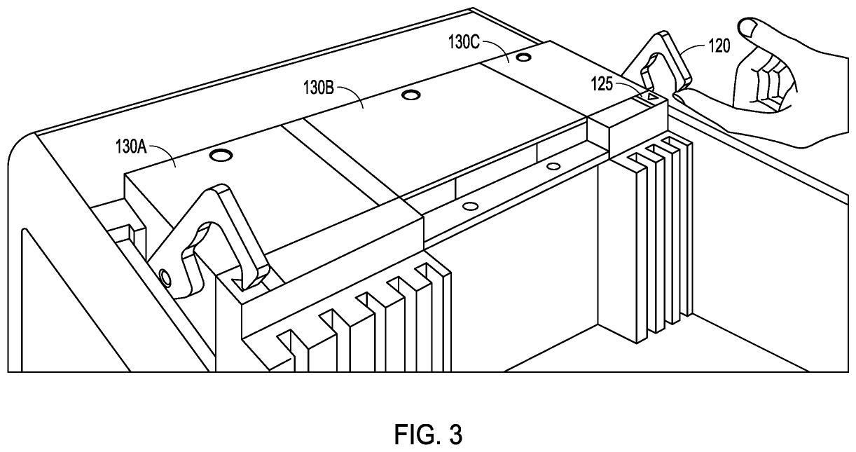

FIG. 3 illustrates the system 100 upon the release of the levers 120 when the release bottoms 125 are pressed. The pressing of the release buttons 125 causes the release of the levers from their installed position to a raised position. The movement from the installed position to the raised position is aided by a spring in the arm of the lever.

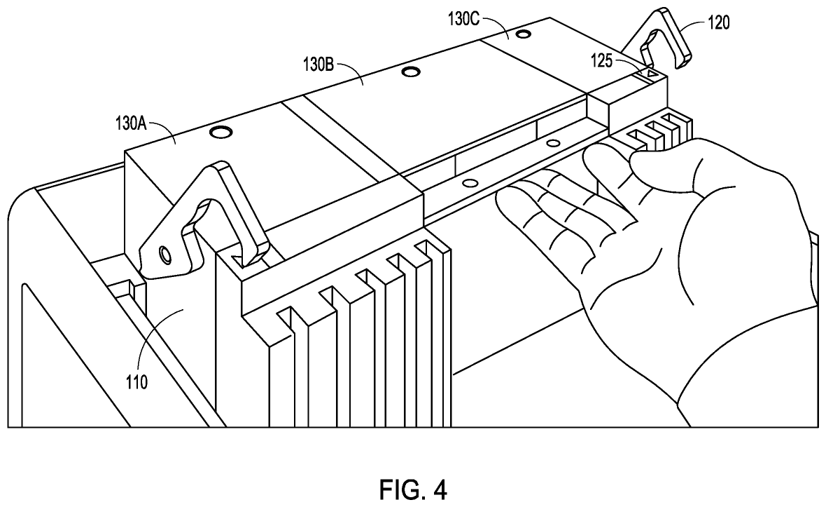

FIG. 4 illustrates how the raised levers and/or the housing can be used to raise the system 100 out of the desktop workstation. It is noted that the installation of the system into a desktop workstation 200 and the removal of the system 100 from the desktop workstation can be accomplished without the use of any tools. There are no screws used to secure the system 100 into the desktop workstation (and no cables are used either). To install the system 100 into a desktop workstation 200, all a person needs to do is position the system 100 in place, put pressure on the housing 110 to line up and couple the electrical connectors 150 to the mother board of the desktop workstation, and then use the levers 120 in a cam-like action to lock down the system 100 into the mother board of the workstation 200. In an embodiment, the electrical connectors 150 on the bottom of the housing 110 have a bit of play or tolerance in them, in order to make installation a bit easier. The electrical couplings are also placed so that they are self-guiding into the mother board.

### Examples

Example No. 1 is a peripheral component interconnect (PCI) for a desktop workstation comprising a housing; a lever attached to a first side of the housing; a compartment comprising one or more fans; a retainer for holding a PCI card; and one or more electrical couplings on a second side of the housing, the one or more electrical couplings configured for coupling to a printed circuit board (PCB) on the workstation.

Example No. 2 includes all the features of Example No. 1, and optionally includes a PCI wherein the lever is operably connected to a release button, the release button for releasing the lever from a first position to a second position.

Example No. 3 includes all the features of Example Nos. 1-2, and optionally includes a PCI wherein the first position is associated with the peripheral component interconnect being installed on the desktop workstation, and the second position is associated with the peripheral component interconnect being removed from the desktop workstation.

Example No. 4 includes all the features of Example Nos. 1-3, and optionally includes a PCI wherein the lever and release button permit a release of the housing from the desktop workstation by hand without a use of a tool.

Example No. 5 includes all the features of Example Nos. 1-4, and optionally includes a PCI wherein the electrical couplings comprise control signal couplings and power couplings.

Example No. 6 includes all the features of Example Nos. 1-5, and optionally includes a PCI comprising a baffle for receiving air flows from the one or more fans.

Example No. 7 includes all the features of Example Nos. 1-6, and optionally includes a PCI wherein the compartment comprising the one or more fans comprises one or more sub-compartments.

Example No. 8 includes all the features of Example Nos. 1-7, and optionally includes a PCI wherein the compartment comprising the one or more fans is removable as a single unit.

Example No. 9 includes all the features of Example Nos. 1-8, and optionally includes a PCI wherein each of the one or more sub-compartments are removable as a single unit.

Example No. 10 includes all the features of Example Nos. 1-9, and optionally includes a PCI wherein the one or more electrical couplings comprise a floating tolerance for coupling to the printed circuit board.

Example No. 11 includes all the features of Example Nos. 1-10, and optionally includes a PCI wherein the printed circuit board comprises a mother board.

Example No. 12 includes all the features of Example Nos. 1-1, and optionally includes a PCI wherein the one or more electrical couplings are configured for direct coupling to the printed circuit board without a use of cables.

Example No. 13 includes all the features of Example Nos. 1-12, and optionally includes a PCI wherein the second side of the housing comprises an underside of the housing.

Example No. 14 includes all the features of Example Nos. 1-13, and optionally includes a PCI comprising a second lever attached to a second side of the housing, the second side of the housing opposite the first side of the housing.

Example No. 15 includes all the features of Example Nos. 1-14, and optionally includes a PCI wherein the lever is operable for insertion of the peripheral component interconnect into the printed circuit board and for removal of the removal of the peripheral component interconnect from the printed circuit board.

Example No. 16 is an apparatus comprising a housing; a lever attached to a first side of the housing; a compartment comprising one or more fans; a retainer for holding a computer card; and one or more electrical couplings on a second side of the housing, the one or more electrical couplings configured for coupling to a printed circuit board (PCB) on a desktop workstation.

Example No. 17 includes all the features of Example No. 16, and optionally includes an apparatus wherein the lever is operably connected to a release button, the release button for releasing the lever from a first position to a second position; wherein the first position is associated with the peripheral component interconnect being installed on the desktop workstation, and the second position is associated is the peripheral component interconnect being removed from the desktop workstation; and wherein the lever and release button permit a release of the housing from the desktop workstation by hand without a use of a tool.

Example No. 18 includes all the features of Example Nos. 16-17, and optionally includes a apparatus wherein the compartment comprising the one or more fans comprises one or more sub-compartments; wherein the compartment comprising the one or more fans is removable as a single unit; and wherein each of the one or more sub-compartments are removable as a single unit.

Example No. 19 includes all the features of Example Nos. 16-18, and optionally includes an apparatus wherein the one or more electrical couplings comprise a floating tolerance for coupling to the printed circuit board; and wherein the one or more electrical couplings are configured for direct coupling to the printed circuit board without a use of cables.

Example No. 20 includes all the features of Example Nos. 16-19, and optionally includes an apparatus wherein the lever is operable for insertion of the peripheral component interconnect into the printed circuit board and for removal of the removal of the peripheral component interconnect from the printed circuit board.

The above detailed description includes references to the accompanying drawings, which form a part of the detailed description. The drawings show, by way of illustration, specific embodiments that may be practiced. These embodiments are also referred to herein as “examples.” Such examples may include elements in addition to those shown or described. However, also contemplated are examples that include the elements shown or described. Moreover, also contemplated are examples using any combination or permutation of those elements shown or described (or one or more aspects thereof), either with respect to a particular example (or one or more aspects thereof), or with respect to other examples (or one or more aspects thereof) shown or described herein.

Publications, patents, and patent documents referred to in this document are incorporated by reference herein in their entirety, as though individually incorporated by reference. In the event of inconsistent usages between this document and those documents so incorporated by reference, the usage in the incorporated reference(s) are supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to suggest a numerical order for their objects.

The above description is intended to be illustrative, and not restrictive. For example, the above-described examples (or one or more aspects thereof) may be used in combination with others. Other embodiments may be used, such as by one of ordinary skill in the art upon reviewing the above description. The Abstract is to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. However, the claims may not set forth every feature disclosed herein as embodiments may feature a subset of said features. Further, embodiments may include fewer features than those disclosed in a particular example. Thus, the following claims are hereby incorporated into the Detailed Description, with a claim standing on its own as a separate embodiment. The scope of the embodiments disclosed herein is to be determined with reference to the appended claims, along with the full scope of equivalents to which such claims are entitled.

1. A peripheral component interconnect (PCI) for a desktop workstation comprising:
a housing;
a lever attached to a first side of the housing;
a compartment comprising one or more fans;
a retainer for holding a PCI card; and
one or more electrical couplings on a second side of the housing, the one or more electrical couplings configured for coupling to a printed circuit board (PCB) on the workstation.

2. The peripheral component interconnect of claim 1, wherein the lever is operably connected to a release button, the release button for releasing the lever from a first position to a second position.

3. The peripheral component interconnect of claim 2, wherein the first position is associated with the peripheral component interconnect being installed on the desktop workstation, and the second position is associated with the peripheral component interconnect being removed from the desktop workstation.

4. The peripheral component interconnect of claim 2, wherein the lever and release button permit a release of the housing from the desktop workstation by hand without a use of a tool.

5. The peripheral component interconnect of claim 1, wherein the electrical couplings comprise control signal couplings and power couplings.

6. The peripheral component interconnect of claim 1, comprising a baffle for receiving air flows from the one or more fans.

7. The peripheral component interconnect of claim 1, wherein the compartment comprising the one or more fans comprises one or more sub-compartments.

8. The peripheral component interconnect of claim 7, wherein the compartment comprising the one or more fans is removable as a single unit.

9. The peripheral component interconnect of claim 7, wherein each of the one or more sub-compartments is removable as a single unit.

10. The peripheral component interconnect of claim 1, wherein the one or more electrical couplings comprise a floating tolerance for coupling to the printed circuit board.

11. The peripheral component device of claim 1, wherein the printed circuit board comprises a mother board.

12. The peripheral component interconnect of claim 1, wherein the one or more electrical couplings are configured for direct coupling to the printed circuit board without a use of cables.

13. The peripheral component interconnect of claim 1, wherein the second side of the housing comprises an underside of the housing.

14. The peripheral component interconnect of claim 1, comprising a second lever attached to a second side of the housing, the second side of the housing opposite the first side of the housing.

15. The peripheral component interconnect of claim 1, wherein the lever is operable for insertion of the peripheral component interconnect into the printed circuit board and for removal of the removal of the peripheral component interconnect from the printed circuit board.

16. An apparatus comprising:
a housing;
a lever attached to a first side of the housing;
a compartment comprising one or more fans;
a retainer for holding a computer card; and
one or more electrical couplings on a second side of the housing, the one or more electrical couplings configured for coupling to a printed circuit board (PCB) on a desktop workstation.

17. The apparatus of claim 16, wherein the lever is operably connected to a release button, the release button for releasing the lever from a first position to a second position;
wherein the first position is associated with the peripheral component interconnect being installed on the desktop workstation, and the second position is associated with the peripheral component interconnect being removed from the desktop workstation; and
wherein the lever and release button permit a release of the housing from the desktop workstation by hand without a use of a tool.

18. The apparatus of claim 16, wherein the compartment comprising the one or more fans comprises one or more sub-compartments; wherein the compartment comprising the one or more fans is removable as a single unit; and wherein each of the one or more sub-compartments is removable as a single unit.

19. The apparatus of claim 16, wherein the one or more electrical couplings comprise a floating tolerance for coupling to the printed circuit board; and wherein the one or more electrical couplings are configured for direct coupling to the printed circuit board without a use of cables.

20. The apparatus of claim 16, wherein the lever is operable for insertion of the peripheral component interconnect into the printed circuit board and for removal of the removal of the peripheral component interconnect from the printed circuit board.
